(19) United States
(12) Patent Application Publication
(10) Pub. No.: US 2019/0081182 A1
(43) Pub. Date: Mar. 14, 2019

(54) OXIDE SEMICONDUCTOR THIN FILM, MANUFACTURING METHOD FOR OXIDE SEMICONDUCTOR THIN FILM, AND THIN FILM TRANSISTOR USING OXIDE SEMICONDUCTOR THIN FILM

(71) Applicant: SUMITOMO METAL MINING CO., LTD., Tokyo (JP)

(72) Inventors: Tokuyuki NAKAYAMA, Ome-shi (JP); Eiichiro NISHIMURA, Ome-shi (JP); Fumihiko MATSUMURA, Ome-shi (JP); Mana SHIRAKI, Ome-shi (JP)

(73) Assignee: SUMITOMO METAL MINING CO., LTD., Tokyo (JP)

(21) Appl. No.: 16/080,510

(22) PCT Filed: Feb. 8, 2017
(86) PCT No.: PCT/JP2017/004584

§ 371 Date: Aug. 28, 2018

(30) Foreign Application Priority Data
Feb. 29, 2016 (JP) 2016-037026

(51) Int. Cl. H01L 29/786; H01L 29/66; H01L 21/02; H01L 21/477

(52) U.S. Cl. CPC H01L 29/78693; H01L 29/78684; H01L 21/477; H01L 21/02565; H01L 21/02631; H01L 29/66742

(57) ABSTRACT

Provided is an oxide semiconductor thin film for which only carrier concentration has been reduced while maintaining a high carrier mobility, as well as a manufacturing method therefor. Provided is an amorphous oxide semiconductor thin film that includes indium and gallium as oxides, further includes hydrogen, has a gallium content such that the molecular ratio Ga/(In+Ga) is 0.15 to 0.55, and has a hydrogen content as measured by secondary ion mass spectrometry of 1.0×10²⁰ atoms/cm³ to 1.0×10²² atoms/cm³.

### TECHNICAL FIELD

The present invention relates to an amorphous or microcrystalline oxide semiconductor thin film, and more specifically, relates to an amorphous or microcrystalline oxide semiconductor thin film in which only the carrier concentration is decreased while a high carrier mobility is maintained by further containing hydrogen to an amorphous or microcrystalline oxide semiconductor thin film which contains indium and gallium as oxides and further hydrogen and has a high carrier mobility.

### BACKGROUND ART

A thin film transistor (TFT) is one kind of field effect transistor (hereinafter referred to as FET). TFT is a three-terminal element equipped with a gate terminal, a source terminal, and a drain terminal as a basic configuration, and it is an active element which uses a semiconductor thin film formed on the surface of the substrate as a channel layer through which an electron or a hole moves as a carrier and has a function of controlling the current flowing through the channel layer by applying a voltage to the gate terminal and switching the current between the source terminal and the drain terminal.

TFT is currently an electronic device which has been the most widely put to practical use, and a representative application thereof is TFT for liquid crystal driving. In number of TFTs for liquid crystal driving, an n-type channel layer through which an electron moves as a carrier is used. Currently, the most widely used n-type channel layer is a low temperature polysilicon thin film or an amorphous silicon thin film.

However, in recent years, the TFT for liquid crystal driving has been also required to drive at a high speed as high definition of liquid crystal is advanced. The driving speed of TFT depends on the electron mobility in the channel layer. In order to realize high speed driving, it is required to use a semiconductor thin film having an electron mobility at least higher than that of amorphous silicon as the channel layer. In low temperature polysilicon, the electron mobility is sufficiently high, but there is a problem, for example, in-plane uniformity is low and the yield is low in a case in which the low temperature polysilicon is formed on a large glass substrate or the cost is high since more steps are required as compared with amorphous silicon and investment in plant and equipment is required.

In order to cope with such a situation, Patent Document 1 proposes a transparent amorphous oxide thin film which is formed by a vapor phase film formation method and composed of elements In, Ga, Zn and O and exhibits semi-insulation properties and in which the composition of the oxide thin film is InGaO₃ (ZnO)ₘ (m is a natural number less than 6) as the composition when being crystallized and the carrier mobility (also referred to as the carrier electron mobility) exceeds 1 cm²V⁻¹sec⁻¹ and the carrier concentration (also referred to as the carrier electron concentration) is 10¹⁶ cm⁻³ or less without addition of an impurity ion and a thin film transistor using this transparent semi-insulating amorphous oxide thin film as a channel layer.

However, the transparent amorphous oxide thin film (a-IGZO film) which is proposed in Patent. Document 1, formed by a vapor phase film formation method such as a sputtering method or a pulsed laser vapor deposition method, and composed of elements In, Ga, Zn and O is pointed out to have an insufficient carrier mobility in the case of being formed as a channel layer of TFT since the electron carrier mobility therein is only briefly in a range of 1 cm²V⁻¹sec⁻¹ or more and 10 cm²V⁻¹sec⁻¹ or less.

Other materials have been investigated in order to solve the insufficient carrier mobility. For example, Patent Document 2 proposes a thin film transistor using an oxide semiconductor thin film in which gallium forms a solid solution in indium oxide, the atomic ratio Ga/(Ga+In) is 0.001 or more and 0.12 or less, the content ratio of indium and gallium with respect to the entire metal atoms is 80 at % or more, and the oxide semiconductor thin film has a bixbyite structure of In₂O₃. As compared with Patent Document 1, in Patent Document 2, the carrier mobility is increased by increasing the indium content and an increase in the carrier concentration is suppressed by crystallizing the oxide semiconductor thin film into a bixbyite structure of In₂O₃, but it is still a problem to be solved that the crystal grain boundary causes variations in properties of TFT in the case of applying the oxide semiconductor thin film to the channel layer of TFT. Furthermore, in Patent Document 2, Examples in which the carrier concentration exceeds 2.0×10¹⁸ cm⁻³ have been found and it is also a problem to be solved that the carrier concentration is slightly high as an oxide semiconductor thin film to be applied to the channel layer of TFT.

In order to solve the high carrier concentration in Patent Document 2, Patent Document 3 proposes a method of manufacturing art oxide semiconductor thin film, which includes forming a film-formed body using a sputtering target at a water partial pressure in the system of 3.0×10⁻⁴ Pa or more and 5.0×10⁻² Pa or less by DC sputtering and crystallizing the film-formed body. In addition, Patent Document 4 proposes a thin film transistor in which the content of hydrogen element contained in the oxide semiconductor film is 0.1 at % or more and 5 at % or less with respect to the entire elements forming the oxide semiconductor thin film. However, all of these are inventions relating to an oxide semiconductor thin film of a crystalline film, knowledge about the influence of hydrogen and the like on oxide semiconductor thin films other than crystalline oxide semiconductor thin films has not been acquired. In addition, there is still the problem of crystal grain boundary which causes important in-plane variations in properties of TFT.

Patent Document. 1: Japanese Unexamined Patent Application, Publication No. 2010-219538
Patent Document 2: PCT International Publication No. WO2010/032422
Patent Document 3: Japanese Unexamined Patent Application, Publication No. 2011-222557
Patent Document 4: PCT International Publication No. WO2010/047077

Non-Patent Document 1: A. Takagi, K. Nomura, H. Ohta, H. Yanaqi, T. Kamiya, M. Hirano, and H. Hosono, Thin Solid Films 486, 38 (2005)

### DISCLOSURE OF THE INVENTION

### Problems to be Solved by the Invention

An object of the present invention is to provide an oxide semiconductor thin film in which only the carrier concentration is decreased while a high carrier mobility is maintained by further containing hydrogen to an amorphous or microcrystalline oxide semiconductor thin film mainly containing indium and gallium as oxides and a method of manufacturing the oxide semiconductor thin film. In addition, the present invention is intended to solve the problem of crystal grain boundary which causes variations in properties of TFT in Patent Documents 2 to 4. Furthermore, another object of the present invention is to provide a suitable manufacturing method different from the crystalline oxide semiconductor thin films of Patent Documents 2 to 4 in order to obtain the amorphous or microcrystalline oxide semiconductor thin film containing mainly indium and gallium as oxides and further hydrogen.

### Means for Solving the Problems

As a result of extensive investigations to solve the problems described above, the present inventors have newly found out that a carrier concentration sufficiently low as a semiconductor is obtained while a carrier mobility of 10 cm²V⁻¹sec⁻¹ or more is maintained as an appropriate amount of hydrogen is contained in an amorphous or microcrystalline oxide semiconductor thin film having an atomic ratio of gallium to the sum of indium and gallium of 0.15 or more and 0.55 or less in terms of Ga/(In+Ga).

A first aspect of the present invention is an amorphous oxide semiconductor thin film containing indium and gallium as oxides and further hydrogen, in which a content of gallium is 0.15 or more and 0.55 or less in terms of an atomic ratio Ga/(In+Ga) and a content of hydrogen measured by secondary ion mass spectrometry is 1.0×10²⁰ atoms/cm³ or more and 1.0×10²² atoms/cm³ or less.

A second aspect of the present invention is a microcrystalline oxide semiconductor thin film containing indium and gallium as oxides and further hydrogen, in which a content of gallium is 0.15 or more and 0.55 or less in term of an atomic ratio Ga/(In+Ga) and a content of hydrogen measured by secondary ion mass spectrometry is 1.0×10²⁰ atoms/cm³ or more and 1.0×10²² atoms/cm³ or less.

A third aspect of the present invention is the oxide semiconductor thin film according to the first or second aspect of the present invention, in which a ratio of an average hydrogen concentration in vicinity of a substrate to an average hydrogen concentration in vicinity of a film surface from 0.50 to 1.20.

A fourth aspect of the present invention is the oxide semiconductor thin film according to any one of the first to third aspects of the present invention, in which OH³¹ is confirmed by time of flight-secondary ion mass spectrometry.

A fifth aspect of the present invention is the oxide semiconductor thin film according to any one of the first to fourth aspects of the present invention, in which a content of gallium is 0.20 or more and 0.35 or less in terms of an atomic ratio Ga/(In+Ga).

A sixth aspect of the present invention is the oxide semiconductor thin film according to any one of the first to third aspects of the present invention, in which a carrier concentration is 2.0×10¹⁸ cm⁻³ or less.

A seventh aspect of the present invention is the oxide semiconductor thin film according to any one of the first to fourth aspects of the present invention, in which a carrier mobility is 10 cm²V⁻¹ sec⁻¹ or more.

An eighth aspect of the present invention is the oxide semiconductor thin film according to any one of the first to fifth aspects of the present invention, in which a carrier concentration is 1.0×10¹⁸ cm⁻³ or less and a carrier mobility is 20 cm²V⁻¹sec⁻¹ or more.

A ninth aspect of the present invention is a thin film transistor equipped with the oxide semiconductor thin film according to any one of the first to sixth aspects of the present invention as a channel layer.

A tenth aspect of the present invention is a method of manufacturing an amorphous oxide semiconductor thin film, the method including a film forming step of forming an oxide thin film on a surface of a substrate using a target including an oxide sintered body containing indium and gallium as oxides in an atmosphere having a water partial pressure in a system of 2.0×10⁻³ Pa or more and 5.0×10⁻¹ Pa or less by a sputtering method and a heat treatment step of subjecting the oxide thin film formed on the surface of the substrate to a heat treatment, in which the oxide semiconductor thin film after being subjected to the heat treatment step contains iridium and gallium as oxides and further hydxogen.

An eleventh aspect of the present invention is a method of manufacturing a microcrystalline oxide semiconductor thin film, the method including a film forming step of forming an oxide thin film on a surface of a substrate using a target including an oxide sintered body containing indium and gallium as oxides in an atmosphere having a water partial pressure in a system of 2.0×10⁻³ Pa or more and 5.0×10⁻¹ Pa or less by a sputtering method and a heat treatment step of subjecting the oxide thin film formed on the surface of the substrate to a heat treatment, in which the oxide semiconductor thin film after being subjected to the heat treatment step contains indium and gallium as oxides and further hydrogen.

A twelfth aspect of the present invention is the method of manufacturing an oxide semiconductor thin film according to the tenth or eleventh aspect of the present invention, in which an atmosphere in a system in the heat treatment step is an atmosphere containing oxygen.

A thirteenth aspect of the present invention is the method of manufacturing an oxide semiconductor than film according to any one of the tenth to twelfth aspects of the present invention, in which a temperature of the substrate in the film forming step is 150° C. or less.

A fourteenth aspect of the present invention is the method of manufacturing an oxide semiconductor thin film according to any one of the tenth to twelfth aspects of the present invention, in which a heat treatment temperature in the heat treatment step is 150° C. or less.

### Effects of the Invention

By containing hydrogen in the amorphous or microcrystalline oxide semiconductor thin film containing indium and gallium as oxides and further hydrogen of the present invention, it is possible to decrease the carrier concentration in the film while maintaining a high carrier mobility. Hence, the thin film transistor (TFT) to which the amorphous or microcrystalline oxide semiconductor thin film is applied as a channel layer stably operates, and as a result, the amorphous or microcrystalline oxide semiconductor thin film of the present invention is industrially significantly useful.

### BRIEF DESCRIPTION OF THE DRAWINGS

FIG. 1 is a diagram illustrating X-ray diffraction measurement results for oxide semiconductor thin films of Example 3 which is an embodiment of the present invention and Comparative Example 4 acquired by X-ray diffraction measurement.

FIG. 2 is a TEM photographic image of a cross-sectional structure of a microcrystalline oxide semiconductor thin film of Example 3 which is an embodiment of the present invention.

FIG. 3 is an electron diffraction diagram of a cross-sectional structure of a microcrystalline oxide semiconductor thin film of Example 3 which is an embodiment of the present invention acquired by TEM-EDX measurement.

FIG. 4 is a TEM photographic image of a cross-sectional structure of an oxide semiconductor thin film which is a crystalline film of Comparative Example 4.

FIG. 5 is an electron diffraction diagram of a cross-sectional structure of an oxide semiconductor thin film which is a crystalline film of Comparative Example 4 acquired by TEM-EDX measurement.

FIG. 6 is a diagram illustrating a change in hydrogen concentration in a film depth direction of an oxide semiconductor thin film of Example 37 which is an embodiment of the present invention acquired by secondary ion mass spectrometry.

FIG. 7 is a diagram illustrating a change in OH⁻ secondary ion intensity in a film depth direction of an oxide semiconductor thin film of Example 38 which is an embodiment of the present invention acquired by time of flight-secondary ion mass spectrometry.

### PREFERRED MODE FOR CARRYING OUT THE INVENTION

Hereinafter, an amorphous or microcrystalline oxide semiconductor thin film, a method of manufacturing an amorphous or microcrystalline oxide semiconductor thin film, and a thin film transistor (TFT) using the amorphous or microcrystalline oxide semiconductor thin film of the present invention will be described in detail. The present invention is not limited to the following description but can be implemented with appropriate modifications as long as the objects of the present invention are achieved.

### 1. Oxide Semiconductor Thin Film

### (1) Composition of Metal

The oxide semiconductor thin film of the present invention is an amorphous or microcrystalline oxide semiconductor thin film which contains indium and gallium as oxides and further hydrogen and has a gallium content of 0.15 or more and 0.55 or less in terms of an atomic ratio Ga/(In+Ga). To be amorphous generally refers to a solid state which does not have long-range regularity such as a crystal structure in the arrangement of constituent atoms. To be microcrystalline generally refers to a state in which a mixed phase of a crystal component having a small crystal grain size (about 1 nm or more and about 100 nm or less) and an amorphous component is formed. To be crystalline generally refers to a state in which the substance has a crystal structure and a distinct diffraction peak corresponding to the index of crystal plane based on the crystal structure is observed in the X-ray diffraction measurement results acquired by the X-ray diffraction measurement.

Incidentally, an amorphous oxide semiconductor thin film can be identified, for example, from the fact that a distinct diffraction peak corresponding to the index of crystal plane based on the crystal structure is not observed in the X-ray diffraction measurement results acquired by the X-ray diffraction measurement and a halo or a halo in which a spot slightly remains is formed and a diffraction pattern consisting of the combination of a spot and a ring is not formed in the electron diffraction diagram of the cross-sectional structure acquired by the TEM-EDX measurement. A microcrystalline oxide semiconductor thin film can be identified, for example, from the fact that a distinct diffraction peak is not observed in the X-ray diffraction measurement results acquired by the X-ray diffraction measurement and a diffraction pattern consisting of the combination of a spot and a ring is formed in the electron diffraction diagram of the cross-sectional structure acquired by the TEM-EDX measurement. A crystalline oxide semiconductor thin film can be identified, for example, from the fact that a distinct diffraction peak corresponding to the index of crystal plane based on the crystal structure is observed in the X-ray diffraction measurement results acquired by the X-ray diffraction measurement and a diffraction spot corresponding to the index of crystal plane based on the crystal structure is formed in the electron diffraction diagram of the cross-sectional structure acquired by the TEM-EDX measurement.

The content of gallium in the oxide semiconductor thin film of the present invention is 0.15 or more and 0.55 or less, preferably 0.20 or more and 0.45 or less, more preferably more than 0.20 and 0.35 or less, still more preferably 0.21 or more and 0.35 or less, and yet still more preferably 0.25 or more and 0.30 or less in terms of an atomic ratio Ga/(In+Ga). Gallium strongly bonds with oxygen and thus has an effect of decreasing the oxygen deficiency amount in the amorphous or microcrystalline oxide semiconductor thin film of the present invention. This effect is not sufficiently obtained in a case in which the content of gallium is less than 0.15 in terms of an atomic ratio Ga/(In+Ga). On the other hand, it is impossible to obtain a sufficiently high carrier mobility of 10 cm²V⁻¹sec⁻¹ or more as an oxide semiconductor thin film in a case in which the content of gallium exceeds 0.55.

The amorphous or microcrystalline oxide semiconductor thin film of the present invention may contain a specific positive trivalent element among elements other than indium and gallium. As the specific positive trivalent element, there are boron, aluminum, scandium, and yttrium. These elements contribute to a decrease in carrier concentration but hardly contribute to the improvement in carrier mobility when being contained in the amorphous or microcrystalline oxide semiconductor thin film of the present invention. It is preferable that the amorphous or microcrystalline oxide semiconductor thin film of the present invention does not contain a positive trivalent element other than the above. In other words, it is preferable that the amorphous or microcrystalline oxide semiconductor thin film of the present invention does not contain lanthanum, praseodymium, dysprosium, holmium, erbium, ytterbium, and lutetium. This is because these elements do not contribute to a decrease in carrier concentration but the carrier mobility decreases.

The amorphous or microcrystalline oxide semiconductor thin film of the present invention may contain tin among elements in positive tetravalency or higher valency. Tin contributes to the increase in carrier mobility in the amorphous or microcrystalline oxide semiconductor thin film. It is preferable that the amorphous or microcrystalline oxide semiconductor thin film of the present invention substantially does not contain elements in positive trivalency or higher valency other than tin as the positive trivalent elements. As the elements in positive tetravalency or higher valency other than tin, there are titanium, zirconium, hafnium, vanadium, niobium, tantalum, chromium, molybdenum, tungsten, manganese, silicon, germanium, lead, antimony, bismuth, and cerium. These elements act as a scattering factor when being contained in the oxide semiconductor thin film of the present invention and thus the carrier mobility in the amorphous or microcrystalline oxide semiconductor thin film decreases.

It is preferable that the amorphous or microcrystalline oxide semiconductor thin film of the present invention substantially does not contain elements in positive divalency or lower valency. As the elements in positive divalency or lower valency, there are lithium, sodium, potassium, rubidium, cesium, magnesium, calcium oxide, strontium, barium, and zinc. These elements contribute to a decrease in carrier concentration to some extent when being contained in the oxide semiconductor of the present invention but the carrier mobility decreases more than the effect since these elements act as a scattering factor.

### (2) Inevitable Impurities

The total amount of inevitable impurities contained in the oxide semiconductor thin film of the present invention is preferably 500 ppm or less, more preferably 300 ppm or less, and still more preferably 100 ppm or less. In the present invention, the inevitable impurities refer to impurities which are not intentionally added hut are inevitably mixed in the manufacturing processes of the respective raw materials and the like. A problem that the carrier concentration increases or the carrier mobility decreases is liable to arise in a case in which the amount of impurities is large.

### (3) Content, Distribution in Film Depth Direction, and Bonding State of Hydrogen

The content of hydrogen contained in the amorphous or microcrystalline oxide semiconductor thin film of the present invention is measured by secondary ion mass spectrometry (SIMS), Rutherford backscattering spectrometry (RBS), hydrogen forward scattering (HFS) analysis, and the like. For example, the content of hydrogen measured by secondary ion mass spectrometry is preferably 1.0×10²⁰ atoms/cm³ or more and 1.0×10²² atoms/cm³ or less, more preferably 3.0×10² atoms/cm³ or more and 5.0×10²¹ atoms/cm³ or less, and still more preferably 5.0×10²⁰ atoms/cm³ or more and 1.0×10²¹ atoms/cm³ or less. It is considered that hydrogen exists in the vicinity of oxygen in the amorphous or microcrystalline oxide semiconductor thin film and contributes to a decrease in the carrier concentration in the oxide semiconductor thin film. It is not preferable that the content of hydrogen in the oxide semiconductor thin film is less than 1.0×10²⁰ atoms/cm³ since the carrier concentration in the oxide semiconductor thin film does not sufficiently decrease to 2.0×10¹⁸ cm⁻³ or less. On the other hand, it is not preferable that the content of hydrogen in the oxide semiconductor thin film exceeds 1.0×10²² atoms/cm³ since excess hydrogen acts as a scattering factor and the carrier mobility in the oxide semiconductor thin film decreases to less than 10 cm²V⁻¹sec⁻¹.

In the amorphous or microcrystalline oxide semiconductor thin film of the present invention, it is preferable that the distribution of contained hydrogen in the film depth direction is as uniform as possible. To be uniform refers to that the ratio of the average hydrogen concentration in the vicinity of the thin film surface to the average hydrogen concentration in the vicinity of the substrate is in a range of from 0.50 to 1.20. It is more preferable when this ratio is in a range of from 0.80 to 1.10.

The average hydrogen concentration in the vicinity of the tom film surface in the present specification means an average value of hydrogen concentrations at five or more random points present between the boundary data that is not affected by the surface in the vicinity of the surface of the oxide semiconductor thin film as a starting point and the point at 10 nm in the positive direction of the film depth by SIMS. The average hydrogen concentration in the vicinity of the substrate in the present specification means an average value of hydrogen concentrations at five or more random points present between the boundary data that is not affected by the substrate in the vicinity of the interface between the substrate and the oxide semiconductor thin film as a starting point and the point at 10 nm in the negative direction of the film depth by SIMS. Incidentally, the positive direction of the film depth by SIMS is a direction from the film surface to the substrate and the negative direction refers to the direction opposite to this direction.

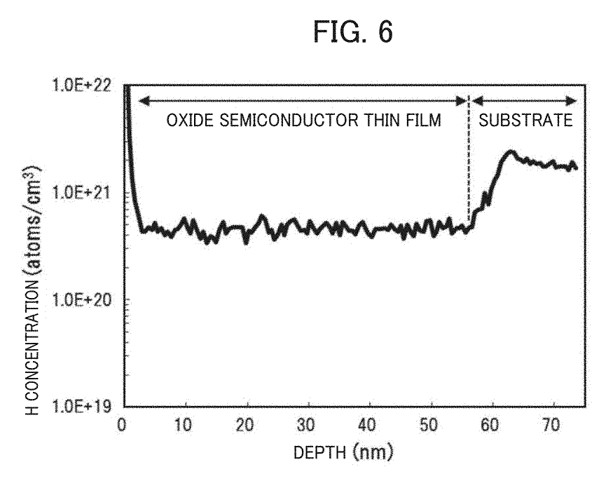

Here, boundary data that is not affected by the surface in the vicinity of the surface of the oxide semiconductor thin film is to be obvious when the measurement result acquired by SIMS is analyzed. For example, in the measurement result acquired by SIMS in FIG. 6, the boundary data that is not affected by the surface in the vicinity of the surface of the oxide semiconductor thin film is the data at 2.8 nm that is the boundary between a range in which the average hydrogen concentration greatly changes in a range of 6.1×10²⁰ to 5.1×10²² atoms/cm³ and the film depth is from 0.2 to 2.3 nm and a range in which the average hydrogen concentration is constant at approximately 4 to 5×10²⁰ atoms/cm³ and the film depth exceeds 2.3 nm. On the often hand, the boundary data that is not affected by the substrate in the vicinity of the interface between the substrate and the oxide semiconductor thin film is the data at 56.6 nm that is the boundary between a range in which the average hydrogen concentration changes to 6.6×10²⁰ atoms/cm³ or more and the film depth is 57.1 nm or more and a range in which the average hydrogen concentration is approximately constant and the film depth is less than 57.1 nm in the same manner. It is possible to determine the average hydrogen concentration in the vicinity of the substrate or the average hydrogen concentration in the vicinity of the surface of the thin film by taking these boundary data as a starting point.

Most of hydrogen contained in the amorphous or microcrystalline oxide semiconductor thin film of the present invent-on exists as OH⁻ generated by bonding of a hydrogen atom or a hydrogen ion with an oxygen ion in an indium oxide phase with a bixbyite structure. OH⁻ exists at a specific lattice position or an interstitial position in the amorphous or microcrystalline oxide semiconductor thin film of the present invention. In particular, OH⁻¹ can be confirmed through the measurement by time of flight-secondary ion mass spectrometry (TOF-SIMS). In contrast, it is not preferable that hydrogen forms a heterogenous phase with indium and/or gallium other than the bixbyite structure.

### (4) Nature of Film

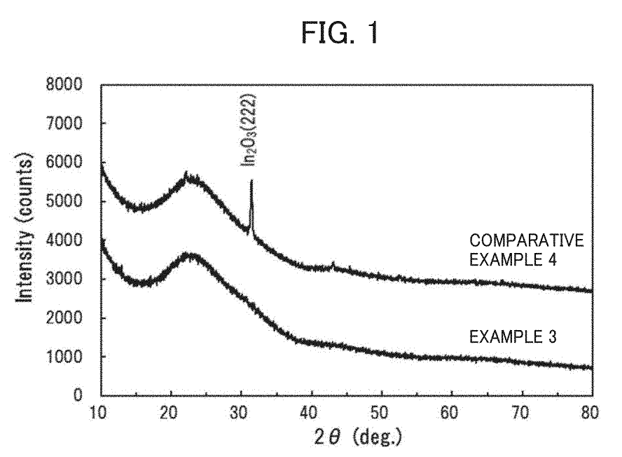

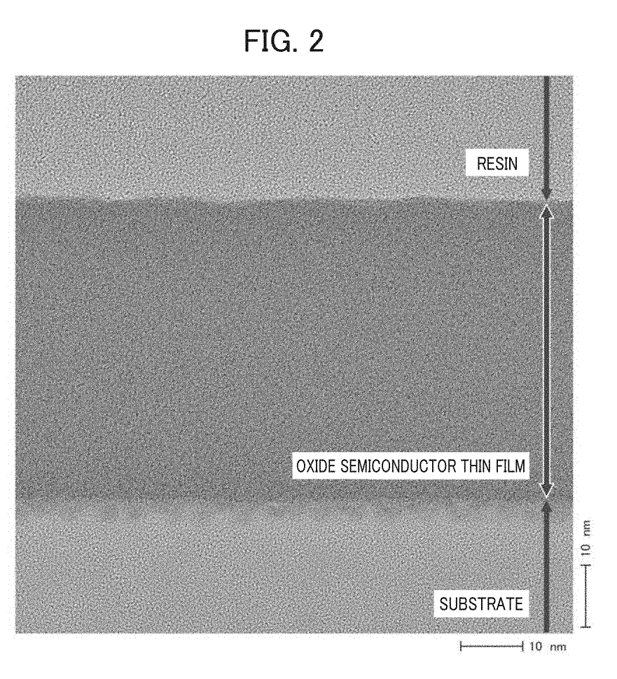

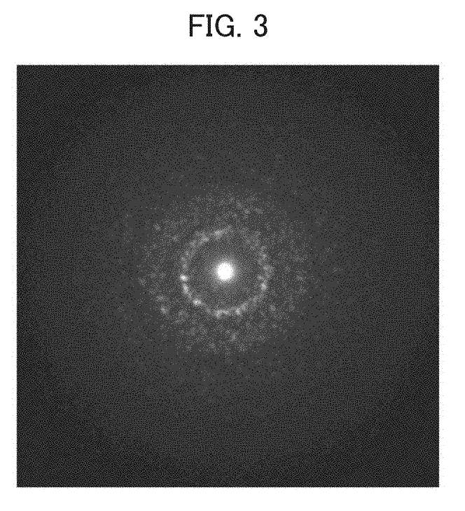

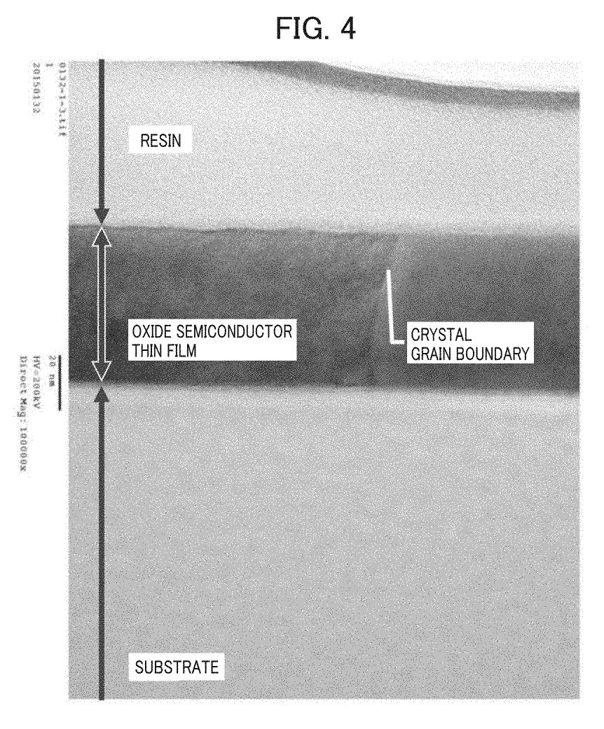

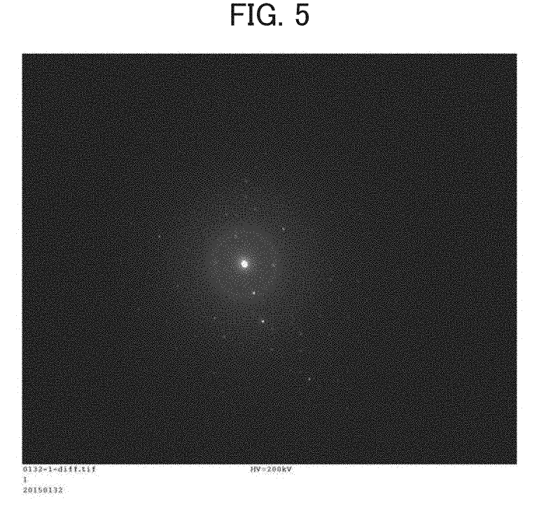

The oxide semiconductor thin film of the present invention is an amorphous or microcrystalline oxide semiconductor thin film. In general, a crystalline film composed of crystals has a distinct diffraction peak corresponding to the index of crystal plane based on the crystal structure in the X-ray diffraction measurement (see Comparative Example 4 in FIG. 1) but an amorphous film composed of amorphous components and a microcrystalline film composed of microcrystals do not have distinct diffraction peaks (see Example 3 in FIG. 1). Even in the case of a microcrystalline film, only a bulge which cannot be clearly recognized as a diffraction peak at the diffraction angle at which the peak attributed to a crystalline film appears can be confirmed in the diffraction pattern. In addition, a crystal grain boundary is confirmed in a crystalline film (see FIG. 4) but a distinct crystal grain boundary is not confirmed in a microcrystalline film as well as an amorphous film (see FIG. 2) when the TEM photographic images of the cross-sectional structures of the respective thin films observed by using a transmission electron microscope (hereinafter written as TEM in some cases) are compared with one another. In the electron diffraction images, a diffraction spot corresponding to the index of crystal plane is confirmed in the case of a crystalline film (see FIG. 5) but only a diffraction pattern consisting of a halo, a halo in which a spot slightly remains, or the combination of a spot and a ring is confirmed in the case of an amorphous film and a microcrystalline film (see FIG. 3).

### (5) Film Thickness

The lower limit of the film thickness of the amorphous or microcrystalline oxide semiconductor thin film of the present invention is preferably 10 nm or more, more preferably 30 nm or more, and yet still more preferably 50 nm or more. On the other hand, the upper limit of the film thickness is not particularly limited but it is preferably 1000 nm or less, more preferably 500 nm or less, and yet still more preferably 300 nm or less, for example, in a case in which the amorphous or microcrystalline oxide semiconductor thin film is applied as a channel layer of a thin film transistor (TFT) of a device requiring flexibility. There is a case in which properties required as a channel layer of a thin film transistor (TFT) cannot be maintained in case of bending the device when the film thickness exceeds 1000 nm. Commonly, it can be said that a film thickness of 30 nm or more and 300 nm or less is suitable when the throughput in the manufacturing process and less variations in performance are taken into consideration.

### (6) Carrier Concentration and Carrier Mobility

The oxide semiconductor thin film of the present invention has a carrier concentration of 2.0×10¹⁸ cm⁻³ or less, and the carrier concentration is more preferably 1.0×10¹⁸ cm⁻³ or less, particularly preferably 8.0×10¹⁷ cm⁻³ or less, and still more preferably 5.0×10¹⁷ cm⁻³ or less. As represented by an amorphous oxide semiconductor thin film which is composed of indium, gallium, and zinc and described in Non-Patent Document 1, the amorphous oxide semiconductor thin film containing a large amount of indium has a carrier concentration of 4.0×10¹⁸ cm⁻⁸ or more and is in a degenerate state and thus a thin film transistor (TFT) in which this is applied as the channel layer does not show normally-off. Hence, the amorphous or microcrystalline oxide semiconductor thin film according to the present invention is convenient since the carrier concentration therein is controlled in a range in which the thin film transistor (TFT) shows normally-off. In addition, the amorphous or microcrystalline oxide semiconductor thin film has a carrier mobility of 10 cm²V⁻¹sec⁻¹ or more, and the carrier mobility is more preferably 15 cm²V⁻¹sec⁻¹ or more and yet still more preferably 20 cm²V⁻¹sec⁻¹ or more.

### 2. Method of Manufacturing Oxide Semiconductor Thin Film

The method of manufacturing an oxide semiconductor thin film of the present invention is not particularly limited. For example, a method of manufacturing an oxide semiconductor thin film can be exemplified which includes a film forming step of forming an oxide thin film on a surface of a substrate using a target composed of an oxide sintered body containing indium and gallium as oxides in an atmosphere having a predetermined water partial pressure in the system by a sputtering method and a heat treatment step of subjecting the oxide thin film formed on the surface of the substrate to a heat treatment.

Hereinafter, a preferred embodiment of the method of manufacturing an oxide semiconductor thin film of the present invention will be described.

### 2-1. Film Forming Step

### (1) Sputtering Method

In the manufacturing method of the present invention, examples of a preferred sputtering method may include a direct current sputtering method, alternating current sputtering at a frequency of 1 MHz or less, and pulse sputtering. In particular, among these, a direct current sputtering method is particularly preferable from the industrial viewpoint. Incidentally, RF sputtering can also be applied, but it is nondirectional, it is thus difficult to establish the conditions for uniform film formation on a large glass substrate, and it is not required to daringly choose RF sputtering.

### (2) Water Partial Pressure

In the film forming step of forming an oxide thin film by a sputtering method in the manufacturing method of the present invention, it is preferable to control the water partial pressure in the system to be in an atmosphere of 2.0×10⁻³ Pa or more and 5.0×10⁻¹ Pa or less, the water partial pressure is more preferably 2.0×10⁻² Pa or more and 2.0×10⁻¹ Pa or less, and it is more preferable to control the water partial pressure to be in an atmosphere of 5.1×10⁻² Pa or more and. 1.0×10⁻¹ Pa or less. It is preferable that water in the system is introduced into the chamber of the sputtering apparatus as water vapor. The amount of hydrogen or hydroxyl group which is a component of water to be incorporated into the oxide thin film is small in a case in which the water partial pressure in the system is less than 2.0×10⁻³ Pa, and it is thus impossible to sufficiently obtain the effect of decreasing the carrier concentration in the oxide semiconductor thin film. On the other hand, the carrier mobility in the oxide semiconductor thin film decreases as well as the carrier concentration in the oxide semiconductor thin film increases in a case in which the water partial pressure in the system exceeds 5.0×10⁻¹ Pa. It is considered that this is because hydrogen or the hydroxyl group behaves as a donor or a scattering factor. Incidentally, the addition of hydrogen to the oxide semiconductor thin film can be replaced with the control of the hydrogen partial pressure in the system instead of the control of the water partial pressure in the system in the present film forming step, but the control of the water partial pressure is preferable since an explosion-proof manufacturing process is required and there is thus a possibility that the cost for securing safety increases in the case of adopting the control of the hydrogen partial pressure in the system.

### (3) Condition of Another Gas

In the present film forming step, as a kind of gas constituting the atmosphere gas for the film formation by a sputtering method, a rare gas, oxygen, and water vapor are preferable, and it is more preferable that the rare gas is particularly argon and water vapor is introduced into the chamber of the sputtering apparatus as water vapor. The total pressure of these atmosphere gases is controlled to be preferably in a range 0.1 Pa or more and 3.0 Pa or less, more preferably in a range of 0.2 Pa or more and 0.8 Pa or less, and still more preferably in a range of 0.3 Pa or more and 0.7 Pa or less.

Among the atmosphere gases in the system, it is important to control not only the water partial pressure in the system but also the oxygen partial pressure in the system. The range of oxygen partial pressure in the system is preferably 9.0×10⁻³ Pa or more and 3.0×10⁻¹ Pa or less, more preferably 1.0×10⁻² Pa or more and 2.0×10⁻¹ Pa or less, and still more preferably 2.5×10⁻² Pa or more and 9.0×10⁻² Pa or less. When the oxygen partial pressure is less than 1.0×10⁻² Pa, a problem arises that the carrier concentration in the oxide semiconductor thin film does not sufficiently decrease or the variations in carrier concentration in the plane of the oxide semiconductor thin film is large. On the other hand, when the oxygen partial pressure in the system exceeds 3.0×10⁻¹ Pa, the ratio of the rare gas, particularly argon, in the atmosphere gas relatively decreases, thus the film forming rate remarkably decreases and the industrial practicality is poor.

It is particularly important to aptly combine the oxygen partial pressure in the system with the water partial pressure in the system in order to optimize the carrier concentration and carrier mobility in the oxide semiconductor thin film of the present invention. It is impossible to decrease the carrier concentration in the oxide semiconductor thin film even when the water partial pressure in the system is controlled in a case in which the oxygen partial pressure in the system is too low. In other words, it is still more preferable to control the oxygen partial pressure in the system to be in a range of 1.0×10⁻² Pa or more and 3.0×10⁻¹ Pa or less and the water partial pressure in the system to be in a range of 5.0×10⁻² Pa or more and 2.0×10⁻¹ Pa or less and it is yet still more preferable to control the oxygen partial pressure in the system to be in a range of 5.0×10⁻² Pa or more and 2.0×10⁻¹ Pa or less and the water partial pressure in the system to be in a range of 5.1×10⁻² Pa or more and 7.5×10⁻¹ Pa or less.

### (4) Substrate

In the present film forming step, as a substrate to be used in film formation, one that is an inorganic material such as alkali glass, alkali-free glass, or quartz glass or an organic material such as polycarbonate, polyarylate, polyether sulfone, polyether nitrile, polyethylene terephthalate, or polyvinyl phenol and is in the form of a plate, sheet, film, or the like can be used. In addition, it may be a substrate composed of a base material in which an inorganic material such as silicon oxide, silicon nitride, silicon oxynitride, aluminum oxide, tantalum oxide, or hafnium oxide or an organic material such as PMA or a fluorine-based polymer is further formed on the substrate described above.

### (5) Substrate Temperature

In the present film forming step, the substrate temperature for the film formation by a sputtering method is preferably room temperature or more and 300° C. or less but the substrate temperature is more preferably 100° C. or more and 300° C. or less. However, excess oxygen is incorporated into the film in some cases when the oxygen partial pressure in the system is 2.4×10⁻² Pa or more at a substrate temperature of less than 100° C. Excess oxygen causes inhibition of a decrease in carrier concentration in the oxide semiconductor thin film or great variations in carrier concentration in the plane of the oxide semiconductor thin film.

Particularly in the case of the amorphous or microcrystalline oxide semiconductor thin film containing indium and gallium as oxides and further hydrogen of the present invention, it is possible to manufacture the oxide semiconductor thin film by conducting a heat treatment in a state in which the temperature is set to, for example, 100° C. or more and 200° C. or less to be lower than that for a conventional oxide semiconductor thin film. For this reason, it is possible to manufacture a thin film transistor (TFT) using, for example, a resin film such as a polyethylene terephthalate (PET) film as a substrate.

### (6) T-S Distance

In the present film forming step, the distance (T-S distance) between the target and the substrate in the film formation by a sputtering method is preferably 150 mm or less, more preferably 110 mm or less, and particularly preferably 80 mm or less. The film forming rate remarkably decreases and the industrial practicality is liable to be poor in a case in which the T-S distance exceeds 150 mm. The T-S distance is preferably 10 mm or more, more preferably 20 mm or more, and particularly preferably 30 mm or more since the oxide thin film to be formed is liable to be damaged by plasma although the film forming rate can be increased and thus the industrial practicality is excellent as the T-S distance is shortened.

### (7) Target

In the present film forming step, it is preferable to use a target composed of an oxide sintered body containing indium and gallium as oxides in the film formation by a sputtering method. It is preferable to use particularly a target composed of an oxide sintered body containing indium and gallium as oxides, but a target composed of an oxide sintered body to which one or more kinds among boron, aluminum, scandium, and yttrium of positive trivalent elements and tin of a positive tetravalent element is further added may be used. It is preferable that the target composed of an oxide sintered body containing indium and gallium as oxides includes at least and In₂O₃ phase with a bixbyite-type structure and it is particularly preferable that the target is configured to further include a GaInO₃ phase with a β-Ga₂O₃-type structure or a GaInO₃ phase with a β-Ga₂O₃-type structure and a (Ga, In)₂O₃ phase as a phase generated other than the In₂O₃ phase. Incidentally, the target may include a composite oxide phase represented by a general formula Ga₃₋ₓIn₅₋ₓSn₂O₁₆ (0.3<x<1.5) in a case in which tin is added to the oxide sintered body. It is preferable that the density of the target composed of the oxide sintered body having such a structure is 6.3 g/cm³ or more. The generation of nodules is caused at the time of mass production in a case in which the density is less than 6.3 g/cm³. In addition, the target is required to exhibit favorable conductivity since it is mainly used in the film formation by direct current sputtering, and it is thus preferable that the target composed of an oxide sintered body is sintered in an oxygen-containing atmosphere and particularly in an oxygen atmosphere.

### 2-2. Heat Treatment Step

The heat treatment step is a step of subjecting the oxide thin film formed on the surface of the substrate to a heat treatment. Defects are excessively introduced into the oxide thin film obtained through the film formation by a sputtering method of a non-equilibrium process. The excessive introduction of defects causes disturbance of the thin film structure such as the arrangement of ions (atoms) and lattices, and this results in an increase in carrier concentration and a decrease in carrier mobility. By conducting a post-treatment, it is possible to decrease the excess defects of the oxide thin film, to restore the structure of the oxide thin film disturbed, and to stabilize the carrier concentration and the carrier mobility. In other words, it is possible to obtain an oxide semiconductor thin film having a high carrier mobility and a carrier concentration appropriately controlled by conducting a post-treatment.

### (1) Heat Treatment Method

As a method for stabilizing the structure, there are a heat treatment and a laser treatment. Specific examples of the heat treatment method may include a rapid thermal annealing (RTA) method utilizing infrared heating or a heat treatment method by lamp heating (LA; lamp annealing). Examples of the laser treatment may include a treatment by an excimer laser or YAG laser using a wavelength which can be absorbed by an oxide semiconductor. A heat treatment such as RTA is preferable when the application of the oxide thin film to a large glass substrate is taken into consideration.

### (2) Heat Treatment Condition

The heat treatment temperature in the heat treatment step can be appropriately selected in a range in which crystallization does not proceed and a range in which the substrate is not deformed or damaged, but it is preferably 100° C. or more and less than 500° C. and more preferably 100° C. or more and 450° C. or less. The heat treatment temperature is preferably 100° C. or more and 300° C. or less and more preferably 100° C. or more and 200° C. or less in the case of using a film substrate made of an organic material, and it is required to be 100° C. or more and 150° C. or less in the case of using a widely useable PET film. The structure of the oxide thin film is liable not to be sufficiently restored and stabilized at a heat treatment temperature less than 100° C. In addition, usable substrates are extremely restricted when the heat treatment temperature is 500° C. or more.

The rate of temperature increase until to have the heat treatment temperature in the heat treatment step is not particularly limited, but it is preferably 10° C./min or more, more preferably 50° C./min or more, and particularly preferably 100° C./min or more. It is possible to conduct the heat treatment while limiting the temperature to the aimed temperature as strictly as possible by increasing the rate of temperature increase. In addition, there is also an advantage that the throughput in the manufacturing process can be increased. With regard to the heat treatment time, the time to be kept at the heat treatment temperature is preferably 1 minute or more and 120 minutes or less and more preferably 5 minutes or more and 60 minutes or less. The heat treatment atmosphere in the heat treatment step is preferably an oxidizing atmosphere and more preferably an oxygen containing atmosphere. As the oxidizing atmosphere, an atmosphere containing oxygen, ozone, water vapor, nitrogen oxide, or the like is preferable. Incidentally, the heat treatment temperature, the heat treatment time, the time of temperature increase, and the atmosphere in the above ranges may be combined with one another.

### (3) Etching Condition

The amorphous or microcrystalline oxide semiconductor thin film of the present invention is subjected to microfabricaton required for an application such as a thin film transistor (TFT) by wet etching or dry etching. Commonly, an appropriate substrate temperature can be selected from temperatures lower than the crystallization temperature, for example, from a range of from room temperature to 300° C. and an oxide thin film can be once formed and then subjected to microfabricaton by wet etching. As the etchant, a weak acid can be generally used but a weak acid containing PAN or oxalic acid as a main component is preferable. For example, ITO-06N manufactured by KANTO CHEMICAL CO., INC. and the like can be used. Dry etching may be selected depending on the configuration of the thin film transistor (TFT).

### 3. Thin Film Transistor (TFT) and Manufacturing Method Thereof

In the case of a thin film transistor (TFT) equipped with the amorphous or microcrystalline oxide semiconductor thin film of the present invention as a channel layer, the thin film transistor (TFT) stably operates since the channel layer is an oxide semiconductor thin film in which the carrier concentration can be decreased while a high carrier mobility is maintained.

The thin film transistor of the present invention is not particularly limited as long as it is a thin film transistor (TFT) equipped with the amorphous or microcrystalline oxide semiconductor thin film of the present invention as a channel layer, but examples thereof may include a thin film transistor equipped with a source electrode, a drain electrode, a gate electrode, a channel layer, and a gate insulating film.

The thin film transistor of the present invention can be manufactured by combining a conventionally known method with the method of manufacturing an oxide semiconductor thin film of the present invention. For example, the following method can be exemplified. A gate insulating film is formed on the surface of a gate electrode. Then, an oxide thin film is formed on the surface of the gate insulating film, subjected to a heat treatment, and etched by the method of manufacturing an amorphous or microcrystalline oxide semiconductor thin film of the present invention to form a patterned oxide semiconductor thin film (channel layer). Then, a source electrode and a drain electrode which are patterned are formed on the surface of the oxide semiconductor thin film (channel layer).

Examples of the method of forming a gate insulating film on the surface of a gate electrode may include a method in which a SiO₂ film (gate insulating film) is formed on the surface of a Si substrate (gate electrode) by thermal oxidation or the like and a method in which a SiO₂ film (gate insulating film) is formed on the surface of an ITO film (gate electrode) by radio frequency magnetron sputtering.

Examples of the method of forming the source electrode and the drain electrode on the surface of the oxide semiconductor thin film (channel layer) may include a method in which a metal thin film of Mo, Al, Ta, Ti, Au, Pt or the like, an alloy thin film of these metals, a conductive oxide or nitride thin film of these metals, various kinds of conductive polymer materials, ITO for transparent TFT or the like is formed on the surface of the oxide semiconductor thin film (channel layer) by a direct current magnetron sputtering method.

As the method of forming the patterned source electrode and drain electrode on the surface of the oxide semiconductor thin film (channel layer), for example, a method in which etching is conducted by utilizing a photolithography technique, a lift-off method, or the like can be used.

### EXAMPLES

Hereinafter, the present invention will be described in more detail using Examples, but the present invention is not limited by these Examples.

### Example 1

An oxide semiconductor thin film was fabricated and evaluated by the process to be described below,

### <Fabrication of Oxide Semiconductor Thin Film>

Film formation by direct current sputtering was conducted using a load-lock type magnetron sputtering apparatus (manufactured by ULVAC, Inc.) equipped with a direct current power supply, a 6-inch cathode, and a quadrupole mass spectrometer (manufactured by INFICON Co., Ltd.). As the target, a target composed of an oxide sintered body containing indium and gallium as oxides was used. The content of gallium in the target was set to 0.27 in terms of an atomic ratio Ga/(In+Ga). In the actual film formation, after pre-sputtering for 10 minutes, the substrate was transported right onto the sputtering target, namely, to the stationary facing position, and an oxide thin film having a film thickness of 50 nm was formed. Details of film forming conditions are presented below.

### [Film Forming Condition]

Substrate temperature: 200° C.
Ultimate vacuum: less than 3.0×10⁻⁵ Pa
Distance between target and substrate (T-S): 60 mm
Total pressure of sputtering gas: 0.6 Pa
Oxygen partial pressure: 6.0×10⁻² Pa
Water partial pressure: 2.2×10⁻³ Pa
Input power: direct current (DC) 300 W

Subsequently, the oxide thin film after being formed was subjected to a heat treatment under the following conditions using a rapid thermal annealing (RTA) apparatus, thereby obtaining an oxide semiconductor thin film.

### [Heat Treatment Condition]

Heat treatment temperature: 350° C.
Atmosphere: oxygen
Rate of temperature increase: 500° C./min

### <Evaluation on Properties of Oxide Semiconductor Thin Film>

The composition of the oxide thin film was examined by ICP atomic emission spectroscopy. The film thickness of the oxide semiconductor thin film was measured by using a surface roughness tester (manufactured by KLA-Tencor Corporation). The carrier concentration and carrier mobility in the oxide semiconductor thin film were determined by using a Hall effect measuring apparatus (manufactured by TOYO Corporation). The nature of film of the oxide thin film before being subjected to the heat treatment step and the oxide semiconductor thin film after being subjected to the heat treatment step was confirmed by X-ray diffraction measurement (manufactured by Koninklijke Phillips N.V.) and a transmission electron microscope and electron diffraction measurement (TEM-EDX, manufactured by Hitachi High-Technologies Corporation and JEOL Ltd.). The results are presented in Table 1 and Table 2.

Among Examples and Comparative Examples above, the representative oxide semiconductor thin films were subjected to the measurement by SIMS (secondary ion mass spectrometry, manufactured by ULVAC-PHI, INC.) to determine the average hydrogen content in the film depth direction. The results are presented in Table 2.

### Examples 2 to 34 and Comparative Examples 1 to 7

Oxide semiconductor thin films were fabricated and evaluated in the same manner as in Example 1 except that the target, the sputtering conditions, and the heat treatment conditions were changed to the targets which were composed of an oxide sintered body containing indium and gallium as oxides and had the compositions presented in Table 1 and the conditions presented in Table 1. The results are collectively presented in Table 1 and Table 2.

TABLE 1

| | Film forming step | | | | | |
|---|---|---|---|---|---|---|
| | | | Total pressure | Oxygen | Water | |
| | Target | Substrate | of sputtering | partial | partial | |
| | Ga/(In + Ga) | temperature | gas | pressure | pressure | |
| | Atomic ratio | (° C.) | (Pa) | (×10⁻² Pa) | (×10⁻² Pa) | Nature of film |
| Comparative | 0.27 | 200 | 0.6 | 1.2 | 0.15 | Microcrystalline |
| Example 1 | | | | | | |
| Comparative | 0.27 | 200 | 0.6 | 14.9 | 0.14 | Microcrystalline |
| Example 2 | | | | | | |
| Example 1 | 0.27 | 200 | 0.6 | 6.0 | 0.28 | Microcrystalline |
| Example 2 | 0.27 | 200 | 0.6 | 5.9 | 2.4 | Microcrystalline |
| Example 3 | 0.27 | 200 | 0.6 | 5.4 | 6.5 | Microcrystalline |
| Example 4 | 0.27 | 200 | 0.6 | 4.3 | 17 | Microcrystalline |
| Example 5 | 0.27 | 200 | 0.6 | 1.1 | 6.5 | Microcrystalline |
| Example 6 | 0.27 | 200 | 0.5 | 13.7 | 4.5 | Microcrystalline |
| Example 7 | 0.27 | 200 | 0.6 | 27.8 | 4.5 | Microcrystalline |
| Example 8 | 0.27 | 25 | 0.6 | 1.2 | 1.2 | Microcrystalline |
| Example 9 | 0.27 | 100 | 0.6 | 8.2 | 5.4 | Microcrystalline |
| Example 10 | 0.27 | 120 | 0.6 | 8.2 | 5.4 | Microcrystalline |
| Example 11 | 0.27 | 150 | 0.5 | 9.0 | 5.1 | Microcrystalline |
| Example 12 | 0.27 | 250 | 0.6 | 1.1 | 6.5 | Microcrystalline |
| Example 13 | 0.27 | 150 | 0.6 | 5.4 | 6.5 | Microcrystalline |
| Example 14 | 0.27 | 200 | 0.1 | 0.98 | 0.28 | Microcrystalline |
| Example 15 | 0.27 | 200 | 0.2 | 1.9 | 0.90 | Microcrystalline |
| Example 16 | 0.27 | 200 | 0.8 | 7.4 | 6.5 | Microcrystalline |
| Example 17 | 0.27 | 200 | 1.5 | 10.5 | 43 | Microcrystalline |
| Comparative | 0.27 | 200 | 1.5 | 10.5 | 60 | Microcrystalline |
| Example 3 | | | | | | |
| Example 18 | 0.27 | 200 | 0.6 | 13.7 | 4.5 | Amorphous |
| Example 19 | 0.27 | 200 | 0.6 | 13.7 | 4.5 | Microcrystalline |
| Example 20 | 0.27 | 200 | 0.6 | 5.4 | 6.5 | Microcrystalline |
| Example 21 | 0.27 | 200 | 0.6 | 5.4 | 6.5 | Microcrystalline |
| Example 22 | 0.27 | 200 | 0.6 | 5.4 | 6.5 | Microcrystalline |
| Comparative | 0.27 | 200 | 0.6 | 5.4 | 6.5 | Microcrystalline |
| Example 4 | | | | | | |
| Comparative | 0.27 | 200 | 0.6 | 13.7 | 6.5 | Crystalline |
| Example 5 | | | | | | |
| Example 23 | 0.27 | 200 | 0.6 | 5.4 | 6.5 | Microcrystalline |
| Comparative | 0.10 | 150 | 0.6 | 2.6 | 7.5 | Microcrystalline |
| Example 6 | | | | | | |
| Example 24 | 0.15 | 150 | 0.6 | 2.6 | 7.5 | Microcrystalline |
| Example 25 | 0.20 | 150 | 0.6 | 2.6 | 7.5 | Microcrystalline |
| Example 26 | 0.21 | 150 | 0.6 | 2.6 | 7.5 | Microcrystalline |
| Example 27 | 0.25 | 150 | 0.6 | 8.2 | 5.4 | Microcrystalline |
| Example 28 | 0.30 | 200 | 0.6 | 5.4 | 6.5 | Microcrystalline |
| Example 29 | 0.35 | 200 | 0.6 | 5.4 | 6.5 | Microcrystalline |
| Example 30 | 0.35 | 200 | 0.6 | 5.4 | 6.5 | Microcrystalline |
| Example 31 | 0.35 | 150 | 0.6 | 5.4 | 6.5 | Microcrystalline |
| Example 32 | 0.45 | 200 | 0.6 | 0.9 | 1.0 | Microcrystalline |
| Example 33 | 0.50 | 250 | 0.6 | 0.9 | 1.0 | Microcrystalline |
| Example 34 | 0.53 | 300 | 0.6 | 0.9 | 1.0 | Microcrystalline |
| Comparative | 0.60 | 300 | 0.6 | 0.9 | 1.0 | Microcrystalline |
| Example 7 | | | | | | |

TABLE 2

| | Heat treatment step | | | Thin film evaluation | | |
|---|---|---|---|---|---|---|
| | | Film | | Carrier | Carrier | Hydrogen |
| | | thickness | Nature of | concentration | mobility | concentration |
| | Heat treatment condition | (nm) | film | (×10¹⁷ cm⁻³) | (cm² V⁻³ sec⁻³) | (atoms/cm³) |
| Ccomparative | 350° C., Oxygen, 30 minutes | 48 | Microcrystalline | 28 | 25.7 | 8.8 × 10¹⁹ |
| Example 1 | | | | | | |
| Comparative | 350° C., Oxygen, 30 minutes | 52 | Microcrystalline | 22 | 25.3 | — |
| Example 2 | | | | | | |
| Example 1 | 350° C., Oxygen, 30 minutes | 53 | Microcrystalline | 16 | 25.6 | 1.3 × 10²⁰ |
| Example 2 | 350° C., Oxygen, 30 minutes | 53 | Microcrystalline | 9.7 | 26.5 | 3.4 × 10²⁰ |
| Example 3 | 350° C., Oxygen, 30 minutes | 81 | Microcrystalline | 7.8 | 26.1 | 5.8 × 10²⁰ |
| Example 4 | 350° C., Oxygen, 30 minutes | 51 | Microcrystalline | 9.8 | 23.3 | 2.4 × 10²¹ |
| Example 5 | 350° C., Oxygen, 30 minutes | 47 | Microcrystalline | 9.9 | 23.6 | — |
| Example 6 | 350° C., Oxygen, 30 minutes | 52 | Microcrystalline | 9.6 | 26.0 | — |
| Example 7 | 350° C., Oxygen, 30 minutes | 60 | Microcrystalline | 8.3 | 19.0 | — |
| Example 8 | 350° C., Oxygen, 30 minutes | 55 | Microcrystalline | 4.7 | 19.3 | — |
| Example 9 | 100° C., Oxygen, 30 minutes | 55 | Microcrystalline | 4.7 | 21.0 | — |
| Example 10 | 120° C., Oxygen, 30 minutes | 53 | Microcrystalline | 3.6 | 23.2 | — |
| Example 11 | 150° C., Oxygen, 30 minutes | 74 | Microcrystalline | 2.3 | 24.1 | — |
| Example 12 | 350° C., Oxygen, 30 minutes | 53 | Microcrystalline | 9.5 | 23.0 | — |
| Example 13 | 150° C., Air, 30 minutes | 48 | Microcrystalline | 2.9 | 24.8 | — |
| Example 14 | 350° C., Oxygen, 30 minutes | 154 | Microcrystalline | 13 | 25.3 | — |
| Example 15 | 350° C., Oxygen, 30 minutes | 153 | Microcrystalline | 11 | 26.1 | — |
| Example 16 | 350° C., Oxygen, 30 minutes | 147 | Microcrystalline | 4.4 | 20.3 | — |
| Example 17 | 350° C., Oxygen, 30 minutes | 60 | Microcrystalline | 8.8 | 19.2 | 9.6 × 10²³ |
| Comparative | 350° C., Oxygen, 30 minutes | 52 | Microcrystalline | 24 | 24.1 | 2.3 × 10²² |
| Example 3 | | | | | | |
| Example 18 | 350° C., Oxygen, 30 minutes | 10 | Amorphous | 20 | 22.4 | — |
| Example 19 | 350° C., Oxygen, 30 minutes | 31 | Microcrystalline | 9.6 | 23.9 | — |
| Example 20 | 350° C., Oxygen, 30 minutes | 141 | Microcrystalline | 4.9 | 25.7 | — |
| Example 21 | 350° C., Oxygen, 30 minutes | 307 | Microcrystalline | 2.3 | 24.3 | — |
| Example 22 | 350° C., Oxygen, 30 minutes | 987 | Microcrystalline | 0.76 | 23.6 | — |
| Comparative | 500° C., Oxygen, 30 minutes | 48 | Crystalline | 22 | 2.6 | — |
| Example 4 | | | | | | |
| Comparative | 350° C., Oxygen, 30 minutes | 1288 | Crystalline | 0.38 | 9.1 | — |
| Example 5 | | | | | | |
| Example 23 | 450° C., Oxygen, 30 minutes | 94 | Microcrystalline | 7.7 | 20.8 | — |
| Comparative | 150° C., Oxygen, 30 minutes | 148 | Microcrystalline | 190 | 49.2 | — |
| Example 6 | | | | | | |
| Example 24 | 150° C., Oxygen, 30 minutes | 155 | Microcrystalline | 12 | 35.2 | — |
| Example 25 | 150° C., Oxygen, 30 minutes | 152 | Microcrystalline | 6.9 | 31.1 | — |
| Example 26 | 150° C., Oxygen, 30 minutes | 147 | Microcrystalline | 5.9 | 30.3 | — |
| Example 27 | 150° C., Oxygen, 30 minutes | 63 | Microcrystalline | 3.2 | 25.1 | — |
| Example 28 | 350° C., Oxygen, 30 minutes | 50 | Microcrystalline | 7.9 | 25.3 | — |
| Example 29 | 350° C., Oxygen, 30 minutes | 170 | Microcrystalline | 1.0 | 20.6 | — |
| Example 30 | 350° C., Oxygen, 30 minutes | 50 | Microcrystalline | 3.4 | 20.2 | — |
| Example 31 | 150° C., Oxygen, 30 minutes | 50 | Microcrystalline | 0.33 | 20.0 | — |
| Example 32 | 350° C., Oxygen, 30 minutes | 47 | Microcrystalline | 0.52 | 12.4 | — |
| Example 33 | 350° C., Oxygen, 30 minutes | 52 | Microcrystalline | 0.29 | 11.3 | — |
| Example 34 | 350° C., Oxygen, 30 minutes | 56 | Microcrystalline | 0.11 | 10.3 | — |
| Comparative | 350° C., Oxygen, 30 minutes | 55 | Microcrystalline | Unmeasurable | Unmeasurable | — |
| Example 7 | | | | | | |

From Examples 1 to 34, it can be seen that in the amorphous or microcrystalline oxide semiconductor thin films which contain indium and gallium as oxides and further hydrogen and have a gallium content of 0.15 or more and 0.55 or less in terms of an atomic ratio Ga/(In+Ga) of the present invention, the carrier concentration in the amorphous or microcrystalline oxide semiconductor thin film is 2.0×10¹⁸ cm⁻¹³ or less and the carrier mobility in the amorphous or microcrystalline oxide semiconductor thin film is 10 cm²V⁻¹sec⁻¹ or more as the oxygen partial pressure in the system is controlled to 9.0×10⁻³ Pa or more and 3.0×10⁻¹ Pa or less and the water partial pressure in the system is controlled to 2.0×10⁻³ Pa or more and 5.0×10⁻¹ Pa or less in the film formation by a sputtering method.

In particular, as can be seen from Examples 2 to 6, 9 to 13, 16, 19 to 23, and 25 to 31, in the amorphous or microcrystalline oxide semiconductor thin films which contain indium and gallium as oxides and further hydrogen and have a gallium content of 0.20 or more and 0.35 or less in terms of an atomic ratio Ga/(In+Ga) of the present invention, it is possible to realize a carrier concentration in the oxide semiconductor thin film of 1.0×10¹⁸ cm⁻³ or less and a carrier mobility in the oxide semiconductor thin film of 20 cm²V⁻¹sec⁻¹ or more by controlling the oxygen partial pressure in the system to 1.0×10⁻² Pa or more and 2.0×10⁻¹ Pa or less and the water partial pressure in the system to 2.0×10⁻² Pa or more and 2.0×10⁻¹ Pa or less in the film formation by a sputtering method.

Furthermore, as in Examples 3, 9 to 11, 13, 16, 20 to 23, and 25 to 31, it is possible to achieve a carrier concentration in the oxide semiconductor thin film of 8.0×10²⁷ cm⁻³ or less and a carrier mobility in the oxide semiconductor thin film of 20 cm²V⁻¹sec⁻¹ or more when the oxygen partial pressure in the system is controlled to be in a range of 2.5×10⁻² Pa or more and 9.0×10⁻² Pa or less and the water partial pressure in the system is controlled to be in a range of 5.1×10⁻² Pa or more and 1.0×10⁻² Pa or less.

In contrast, in Comparative Examples 1 and 2, the water partial pressure in the system is less than 2.0×10⁻³ Pa, thus hydrogen is not sufficiently contained in the oxide semiconductor thin film, and as a result, the content of hydrogen in the oxide semiconductor thin film of Comparative Example 1 acquired by secondary ion mass spectrometry is less than 1.0×10²⁰ atoms/cm³ and the carrier concentration in the oxide semiconductor thin films of Comparative Examples 1 and 2 exceeds 2.0×10¹⁸ cm⁻³. On the other hand, in Comparative Example 3, the water partial pressure in the system exceeds 6.0×10⁻¹ Pa, thus the content of hydrogen in the oxide semiconductor thin film acquired by secondary ion mass spectrometry is 1.0×10²² atoms/cm³ and the carrier concentration in the oxide semiconductor thin film exceeds 2.0×10¹⁸ cm⁻³.

Furthermore, in Comparative Example 4, a crystalline film is formed since the heat treatment temperature is increased to be higher than that in Example 3. In Comparative Example 5, the crystallization temperature is decreased and a crystalline film is formed since the film thickness is set to be more than 1000 nm. In these Comparative Examples 4 and 5, not only the carrier mobility in the oxide semiconductor thin film is less than 10 cm²V⁻¹sec but also the carrier concentration in the oxide semiconductor thin film exceeds 2.0×10¹⁸ cm⁻³ in some cases. In other words, the crystalline films mainly composed of indium, gallium, oxygen, and hydrogen of Patent Documents 2 to 4 are intended to cope with deterioration in semiconductor properties unlike the microcrystalline or amorphous oxide semiconductor thin film of the present invention.

In addition, in Comparative Example 6, the gallium content is 0.10 in terms of an atomic ratio Ga/(In+Ga) to be less than the range of the present invention. For this reason, a result is obtained that the carrier concentration in the oxide semiconductor thin film is too high even when the oxygen partial pressure and water partial pressure in the system are controlled. In addition, in Comparative Example 7, gallium content is 0.60 in terms of an atomic ratio Ga/(In+Ga) to exceed the range of the present invention, and in this case, the carrier mobility in the oxide semiconductor thin film is too low and the Hall effect measurement itself cannot be thus aptly conducted.

In addition, from Examples 9 to 11, 27 and 31, with regard to the microcrystalline oxide semiconductor thin films which contain indium and gallium as oxides and further hydrogen and have a gallium content of 0.25 or more and 0.35 or less in terms of an atomic ratio Ga/(In+Ga) of the present invention, an oxide thin film is formed on the surface of the substrate in a state in which the temperature of the substrate is set to a low temperature of 150° C. or less in the film forming step of forming an oxide thin film and the oxide thin film formed on the surface of the substrate is subjected to a heat treatment at a low temperature of 150° C. or less in an internal atmosphere of the system containing oxygen in the heat treatment step of subjecting the oxide thin film to a heat treatment. It is possible to achieve a carrier concentration in the oxide semiconductor thin film of 5.0×10¹⁷ cm⁻³ or less and a carrier mobility in the oxide semiconductor thin film of 20 cm²V⁻¹sec⁻¹ or more even by such a low temperature process.

The content of hydrogen in the oxide semiconductor thin film was measured by secondary ion mass spectrometry, and as a result, the content of hydrogen in Example 1 was 1.3×10²⁰ atoms/cm³. In the same manner, the content of hydrogen in Example 2, Example 3, Example 4, and Example 17 was 3.4×10²⁰ atoms/cm³, 5.8×10²⁰ atoms/cm³, 2.4×10²¹ atoms/cm³, and 9.6×10²¹ atoms/cm³, respectively. In contrast, the content of hydrogen in Comparative Example 1 was 8.8×10⁹ atoms/cm³ to be less than the range of the present invention and the content of hydrogen in Comparative Example 3 was 2.3×10²² atom/cm³ to exceed the range of the present invention.

### <X-Ray Diffraction Measurement and TEM-EDX Measurement of Cross-Sectional Structure>

The oxide semiconductor thin films of Example 3 and Comparative Example 4 were subjected to X-ray diffraction measurement and TEM-EDX measurement of cross-sectional structure. The X-ray diffraction measurement results for the oxide semiconductor thin film of Example 3 and Comparative Example 4 acquired by X-ray diffraction measurement are illustrated in FIG. 1, a TEM photographic image of a cross-sectional structure of the oxide semiconductor thin film of Example 3 is illustrated in FIG. 2, and an electron diffraction diagram of a cross-sectional structure of the oxide semiconductor thin film of Example 3 acquired by TEM-EDX measurement is illustrated in FIG. 3. It can be seen that an oxide semiconductor thin film other than a crystalline oxide semiconductor thin film is generated from the fact that a distinct diffraction peak attributed to the bixbyite structure of In₂O₃ is not observed in the X-ray diffraction measurement result for the oxide semiconductor thin film of Example 3 in FIG. 1. In addition, it can be seen that a clear crystal grain boundary is not confirmed in the cross-sectional structure of the oxide semiconductor thin film of Example 3 from the TEM photographic image of the cross-sectional structure of the oxide semiconductor thin film in FIG. 2. Furthermore, it can be seen that not an amorphous oxide semiconductor thin film but a microcrystalline oxide semiconductor thin film is generated from the fact that the electron diffraction diagram of the cross-sectional structure of the oxide semiconductor thin film of Example 3 in FIG. 3 acquired by TEM-EDX measurement is a diffraction pattern consisting of the combination of a spot and a ring.

A TEM photographic image of a cross-sectional structure of the oxide semiconductor thin film of Comparative Example 4 is illustrated in FIG. 4 and an electron diffraction diagram of a cross-sectional structure of the oxide semiconductor thin film of Comparative Example 4 acquired by TEM-EDX measurement is illustrated in FIG. 5. It can be seen that a clear crystal grain boundary exists in the TEM photographic image of the cross-sectional structure of the oxide semiconductor thin film of Comparative Example 4 in FIG. 4. In addition, a diffraction spot corresponding to the index of crystal plane based on the bixbyite structure is confirmed in the electron diffraction diagram of the cross-sectional structure of the oxide semiconductor thin film of Comparative Example 4 in FIG. 5 acquired by TEM-EDX measurement. Furthermore, a distinct diffraction peak attributed to the bixbyite structure of In₂O₃ is observed in the X-ray diffraction measurement result for the oxide semiconductor thin film of Comparative Example 4 in FIG. 1. In other words, it can be seen that Example 3 is a microcrystalline film but Comparative Example 4 is a crystalline film and the two films have completely different nature of film.

Next, a thin film transistor was fabricated and evaluated by the process to be described below.

### <Fabrication of Thin Film Transistor and Evaluation on Operating Characteristic>

### Example 35

A thin film transistor (TFT) was fabricated using a conductive p-type Si substrate which had a thickness of 475 μm and a size of 20 mm² and on which a SiO₂ film having a thickness of 100 nm was formed by thermal oxidation. Here, the SiO₂ film functions as a gate insulating film and the conductive p-type Si substrate functions as a gate electrode. The oxide thin film (atomic ratio Ga/(In+Ga)=0.27) of Example 3 was formed on the SiO₂ film gate insulating film. Incidentally, the sputtering conditions were conformed to those in Example 3. The oxide thin film was patterned by photolithography using a resist (OFPR #800 manufactured by TOKYO OHKA KOGYO CO., LTD.) and an etchant (ITO-06N manufactured by KANTO CHEMICAL CO., INC.).

Next, the oxide thin film was subjected to a heat treatment under the conditions conforming to those in Example 3, thereby obtaining an oxide semiconductor thin film of a microcrystalline film. In this manner, the oxide semiconductor thin film of a microcrystalline film was prepared as a channel layer. A source electrode and a drain electrode which were composed of an Au/Ti multilayer film were formed by forming a Ti film having a thickness of 10 nm and an Au film having a thickness of 50 nm on the surface of the channel layer in this order by a direct current magnetron sputtering method. Patterning was conducted by a lift-off method and a source electrode and a drain electrode were formed so as to have a channel length of 20 μm and a channel width of 500 μm, thereby obtaining a thin film transistor of Example 35. The operating characteristics of the thin film transistor were evaluated by using a semiconductor parameter analyzer (manufactured by Agilent Technologies, Inc.). As a result, the operating characteristics as a thin film transistor have been confirmed. In addition, it has been confirmed that the thin film transistor of Example 35 had favorable values of 39.5 cm²V⁻¹sec⁻¹ for the electron field-effect mobility, 4×10⁷ for the on/off ratio, and 0.42 for the S value.

### Example 36

A TFT was fabricated using a polyethylene terephthalate (PET) film having a thickness of 188 μm as a substrate. A SiO₂ film having a film thickness of 150 nm was formed on one side of the PET film by radio frequency magnetron sputtering in advance. An ITO film as a gate electrode was formed on the SiO₂ film. The ITO film was patterned into a desired shape by photolithography in the same manner as in Example 35. Next, a SiO₂ film was again formed on the ITO gate electrode by radio frequency magnetron sputtering and used as a gate insulating film. The oxide thin film (atomic ratio Ga/(In+Ga)=0.35) of Example 31 was formed on the SiO₂ gate insulating film. Incidentally, the sputtering conditions were conformed to those in Example 31.

After patterning by the same photolithography as in Example 35, an annealing treatment was conducted under the conditions conforming to those in Example 31, thereby obtaining a channel layer composed of an oxide semiconductor thin film of a microcrystalline film. An ITO film having a thickness of 100 nm was formed on the surface of the channel layer by a direct current magnetron sputtering method. Patterning was conducted by a lift-off method, and a source electrode and a drain electrode were formed so as to have a channel length of 20 μm and a channel width of 500 μm, thereby obtaining a thin film transistor of Example 36. The operating characteristics of the thin film transistor were evaluated by using a semiconductor parameter analyzer (manufactured by Agilent Technologies, Inc.). As a result, the operating characteristics as a thin film transistor have been confirmed. In addition, it has been confirmed that the thin film transistor of Example 36 had favorable values of 27.8 cm²V⁻¹sec⁻² for the electron feld-effect mobility, 7×10⁷ for the on/off ratio, and 0.36 for the S value. From the above, it has been confirmed that a thin film transistor (TFT) exhibiting favorable operating characteristics can be manufactured using a resin film such as a polyethylene terephthalate (PET) film as a substrate.

### <Measurement of Hydrogen Concentration Distribution in Film Depth Direction by SIMS>

### Example 37

An oxide semiconductor thin film was fabricated in the same manner as in Example 1 except that the oxygen partial pressure at the time of film formation was changed to 5.4×10⁻² Pa and the water partial pressure was changed to 6.5×10⁻² Pa in Example 1. The film thickness of the thin film thus obtained was 52 nm. Incidentally, this thin film corresponds to the film of Example 3 of which the film thickness is decreased. The hydrogen concentration distribution in the film depth direction of such a thin film was measured by SIMS. The measurement results acquired by SIMS are illustrated in FIG. 6. The average hydrogen concentration at 10 random points which were not affected by the surface, were in the vicinity of the surface of the thin film, and were present between the outermost surface of the oxide semiconductor thin film in the film depth direction and the point at 2.8 nm to 7.5 nm was determined, and as a result, it was 4.4×10²⁰ atoms/cm³. Next, the average hydrogen concentration at 10 random points which were not affected by the substrate, were in the vicinity of the substrate, and were present between the outermost surface of the oxide semiconductor thin film in the film depth direction and the point at 51.8 to 56.6 nm was determined, and as a result, it was 4.8×10²° atoms/cm³. From these values, the ratio of the average hydrogen concentration in the vicinity of the thin film surface to the average hydrogen concentration in the vicinity of the substrate was 0.93.

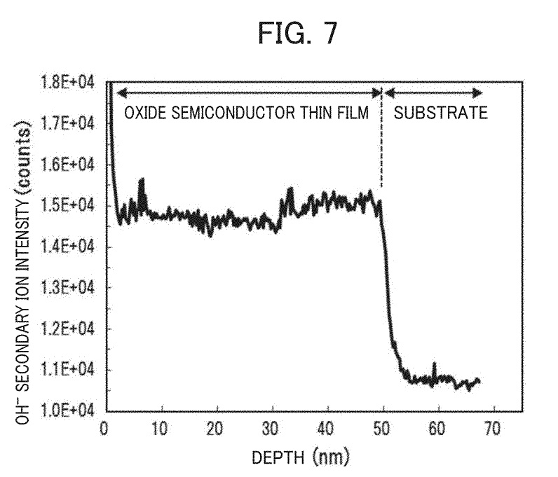

Subsequently, this thin film was subjected to the measurement by TOF-SIMS. A change in OH⁻ secondary ion intensity in the thin film depth direction through the measurement by TOF-SIMS is illustrated in FIG. 7. From this result, it has been confirmed that OH⁻ exists in the oxide semiconductor thin film of the present Example and is uniformly distributed in the film depth direction.

### Example 38

An oxide semiconductor thin film was fabricated in the same manner as in Example 1 except that the oxygen partial pressure at the time of film formation was changed to 9.3×10⁻² Pa and the water partial pressure was changed to 2.1×10⁻² Pa. The film thickness of the thin film intended to have a film thickness of 150 nm was 149 nm. The air was used as the atmosphere for the heat treatment. The ratio of the average hydrogen concentration in the vicinity of the thin film surface to the average hydrogen concentration in the vicinity of the substrate was determined in the same manner as in Example 37, and as a result, it was 1.08. In addition, it has been confirmed that OH⁻ exists in the oxide semiconductor thin film and is uniformly distributed in the film depth direction in the present Example as well through the measurement by TOF-SIMS.

1. An amorphous oxide semiconductor thin film comprising: indium and gallium as oxides and
further hydrogen, wherein
a content of gallium is 0.15 or more and 0.55 or less in terms of an atomic ratio Ga/(In+Ga), and
a content of hydrogen measured by secondary ion mass spectrometry is 1.0×10²⁰ atoms/cm³ or more and 1.0×10²² atoms/cm³ or less.

2. A microcrystalline oxide semiconductor thin film comprising: indium and gallium as oxides and
further hydrogen, wherein
a content of gallium is 0.15 or more and 0.55 or less in terms of an atomic ratio Ga/(In+Ga), and
a content of hydrogen measured by secondary ion mass spectrometry is 1.0×10²⁰ atoms/cm³ or more and 1.0×10²² atoms/cm³ or less.

3. The oxide semiconductor thin film according to claim 1, wherein a ratio of an average hydrogen concentration in vicinity of a film surface to an average hydrogen concentration in vicinity of a substrate is from 0.50 to 1.20.

4. The oxide semiconductor thin film according to claim 1, wherein OH− is confirmed by time of flight-secondary ion mass spectrometry.

5. The oxide semiconductor thin film according to claim 1, wherein a content of gallium is 0.20 or more and 0.35 or less in terms of an atomic ratio Ga/(In+Ga).

6. The oxide semiconductor thin film according to claim 1, wherein a carrier concentration is 2.0×10¹⁸ cm⁻³ or less.

7. The oxide semiconductor thin film according to any one of claim 1, wherein a carrier mobility is 10 cm²V⁻¹sec⁻¹ or more.

8. The oxide semiconductor thin film according to claim 1, wherein a carrier concentration is 1.0×10¹⁸ cm⁻³ or less and a carrier mobility is 20 cm²V⁻¹sec⁻¹ or more.

9. A thin film transistor comprising the oxide semiconductor thin film according to claim 1 as a channel layer.

10. A method of manufacturing an amorphous oxide semiconductor thin film, the method comprising:
a film forming step of forming an oxide thin film on a surface of a substrate using a target including an oxide sintered body containing indium and gallium as oxides in an atmosphere having a water partial pressure in a system of 2.0×10⁻³ Pa or more and 5.0×10⁻¹ Pa or less by a sputtering method; and
a heat treatment step of subjecting the oxide thin film formed on the surface of the substrate to a heat treatment, wherein
the oxide semiconductor thin film after being subjected to the heat treatment step contains indium and gallium as oxides and further hydrogen.

11. A method of manufacturing a microcrystalline oxide semiconductor thin film, the method comprising:
a film forming step of forming an oxide thin film on a surface of a substrate using a target including an oxide sintered body containing indium and gallium as oxides in an atmosphere having a water partial pressure in a system of 2.0×10⁻³ Pa or more and 5.0×10⁻¹ Pa or less by a sputtering method; and
a heat treatment step of subjecting the oxide thin film formed on the surface of the substrate to a heat treatment, wherein
the oxide semiconductor thin film after being subjected to the heat treatment step contains indium and gallium as oxides and further hydrogen.

12. The method of manufacturing an oxide semiconductor thin film according to claim 10, wherein an atmosphere in a system in the heat treatment step is an atmosphere containing oxygen.

13. The method of manufacturing an oxide semiconductor thin film according to claim 10, wherein a temperature of the substrate in the film forming step is 150° C. or less.

14. The method of manufacturing an oxide semiconductor thin film according to claim 10, wherein a heat treatment temperature in the heat treatment step is 150° C. or less.

15. The oxide semiconductor thin film according to claim 2, wherein a ratio of an average hydrogen concentration in vicinity of a film surface to an average hydrogen concentration in vicinity of a substrate is from 0.50 to 1.20.

16. The oxide semiconductor thin film according to claim 2, wherein OH⁻ is confirmed by time of flight-secondary ion mass spectrometry.

17. The oxide semiconductor thin film according to claim 2, wherein a content of gallium is 0.20 or more and 0.35 or less in terms of an atomic ratio Ga/(In+Ga).

18. The oxide semiconductor thin film according to claim 2, wherein a carrier concentration is 2.0×10¹⁸ cm⁻³ or less.

19. The oxide semiconductor thin film according to claim 2, wherein a carrier mobility is 10 cm²V⁻¹sec⁻¹ or more.

20. The oxide semiconductor thin film according to claim 2, wherein a carrier concentration is 1.0×10¹⁸ cm⁻³ or less and a carrier mobility is 20 cm²V⁻¹sec⁻¹ or more.
